(19) United States
(12) Patent Application Publication
(10) Pub. No.: US 2014/0225169 A1
(43) Pub. Date: Aug. 14, 2014

(54) Gate All Around Semiconductor Device

(71) Applicant: SAMSUNG ELECTRONICS CO., LTD., Suwon-si (KR)

(72) Inventors: Sung-Dae Suk, Seoul (KR); Dae-Won Ha, Seoul (KR); Su-Yeon Park, Busanjin-gu (KR)

(73) Assignee: Samsung Electronics Co., Ltd., Suwon-si (KR)

(21) Appl. No.: 13/832,017

(22) Filed: Mar. 15, 2013

(30) Foreign Application Priority Data
Feb. 12, 2013 (KR) 10-2013-0014989

(51) Int. Cl. H01L 29/78

(52) U.S. Cl. CPC H01L 29/78
USPC 257/288

(57) ABSTRACT

A gate all around (GAA) type semiconductor device is provided. The GAA type semiconductor device includes source/drain layers formed to be spaced apart from each other, a channel layer connecting the source/drain layers, and a gate electrode formed along the periphery of at least a portion of the channel layer, wherein lower portions of the source/drain layers are formed more deeply than the channel layer, and an insulation pattern is formed between the lower portions of the source/drain layers and lower portions of the gate electrode.

### CROSS-REFERENCE TO RELATED APPLICATION

This application claims priority from Korean Patent Application No. 10-2013-0014989 filed on Feb. 12, 2013 in the Korean Intellectual Property Office, and all the benefits accruing therefrom under 35 U.S.C. 119, the contents of which in its entirety are herein incorporated by reference.

### BACKGROUND

The present inventive concept relates to a gate all around (GAA) type semiconductor devices.

As semiconductor devices are becoming highly integrated, a size of an active region has been reduced, and thus a channel length of a transistor formed in the active region has been reduced. As the channel length of the MOS transistor is reduced, a short channel effect, e.g., an effect of a source/drain region on an electric field of a channel region, may be increased and a channel driving capability of a gate electrode may be deteriorated. In a GAA type semiconductor device, a channel is surrounded by a gate electrode, and an effect of a source/drain region on an electric field of a channel region may be reduced to suppress a short channel effect.

### SUMMARY

The present inventive concept provides a gate all around (GAA) type semiconductor device, which can reduce resistance of a source/drain region.

The present inventive concept also provides a GAA type semiconductor device, which can increase boosting of a source/drain region.

These and other objects of the present inventive concept will be described in or be apparent from the following description of the preferred embodiments.

According to an aspect of the present inventive concept, there is provided a gate all around (GAA) type semiconductor device including source/drain layers formed to be spaced apart from each other, a channel layer connecting the source/drain layers, and a gate electrode formed along the periphery of at least a portion of the channel layer, wherein lower portions of the source/drain layers are formed more deeply than the channel layer, and an insulation pattern is formed between the lower portions of the source/drain layers and lower portions of the gate electrode.

According to another aspect of the present inventive concept, there is provided a gate all around (GAA) type semiconductor device including source/drain layers formed to be spaced apart from each other, a channel layer connecting the source/drain layers, a gate electrode formed along the periphery of at least a portion of the channel layer, a gate insulation layer surrounding the periphery of at least a portion of the channel layer and positioned between the channel layer and the gate electrode, and a spacer formed on the gate electrode and between upper portions of the source/drain layers, wherein a lower portion of the gate electrode is formed to the same depth as the lower portions of the source/drain layers.

Some embodiments are directed to semiconductor devices that include source/drain layers that are formed at a first depth in a substrate and spaced apart from each other, a channel layer that is formed at a second depth in the substrate that is less deep than the first depth and connecting the source/drain layers, a gate electrode that is formed along a periphery of at least a portion of the channel layer, and an insulation pattern that is formed between lower portions of the source/drain layers and corresponding lower portions of the gate electrode.

It is noted that aspects of the inventive concept described with respect to one embodiment, may be incorporated in a different embodiment although not specifically described relative thereto. That is, all embodiments and/or features of any embodiment can be combined in any way and/or combination. These and other objects and/or aspects of the present inventive concept are explained in detail in the specification set forth below.

### BRIEF DESCRIPTION OF THE DRAWINGS

The accompanying figures are included to provide a further understanding of the present inventive concept, and are incorporated in and constitute a part of this specification. The drawings illustrate some embodiments of the present inventive concept and, together with the description, serve to explain principles of the present inventive concept.

FIG. 1 is a perspective view illustrating a GAA type semiconductor device according to some embodiments of the present inventive concept.

FIG. 2 is a cross-sectional view illustrating the GAA type semiconductor device according to embodiments of the present inventive concept, taken along the line A-A′ of FIG. 1.

FIG. 3 is a cross-sectional view illustrating the GAA type semiconductor device according to embodiments of the present inventive concept, taken along the line B-B′ of FIG. 1.

FIG. 4 is a cross-sectional view illustrating an application example of the GAA type semiconductor device according to embodiments of the present inventive concept, taken along the same line as the line A-A′ of FIG. 1.

FIG. 5 is a cross-sectional view illustrating an application example of the GAA type semiconductor device according to embodiments of the present inventive concept, taken along the same line as the line B-B′ of FIG. 1.

FIG. 6 is a cross-sectional view illustrating a GAA type semiconductor device according to some embodiments of the present inventive concept, taken along the same line as the line A-A′ of FIG. 1.

FIG. 7 is a cross-sectional view illustrating the GAA type semiconductor device according to embodiments of the present inventive concept, taken along the same line as the line B-B′ of FIG. 1.

FIGS. 8 to 17 are perspective views illustrating intermediate process operations for explaining example fabricating methods of the GAA type semiconductor device according to some embodiments of the present inventive concept.

FIG. 18 is a perspective view illustrating intermediate process operation for explaining example fabricating methods of an application example of the GAA type semiconductor device according to some embodiments of the present inventive concept.

FIGS. 19 and 20 are perspective views illustrating intermediate process operations for explaining example fabricating methods of the GAA type semiconductor device according to some embodiments of the present inventive concept.

FIG. 21 is a block diagram of an electronic system including semiconductor devices according to some embodiments of the present inventive concept.

### DETAILED DESCRIPTION OF THE EMBODIMENTS

The present inventive concept will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art. The same reference numbers indicate the same components throughout the specification. In the attached figures, the thickness of layers and regions is exaggerated for clarity.

It will also be understood that when a layer is referred to as being “on” another layer or substrate, it can be directly on the other layer or substrate, or intervening layers may also be present. In contrast, when an element is referred to as being “directly on” another element, there are no intervening elements present.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which this invention belongs. It is noted that the use of any and all examples, or exemplary terms provided herein is intended merely to better illuminate the invention and is not a limitation on the scope of the invention unless otherwise specified. Further, unless defined otherwise, all terms defined in generally used dictionaries may not be overly interpreted.

The present inventive concept will be described with reference to perspective views, cross-sectional views, and/or plan views, in which preferred embodiments of the invention are shown. Thus, the profile of an exemplary view may be modified according to manufacturing techniques and/or allowances. That is, the embodiments of the invention are not intended to limit the scope of the present inventive concept but cover all changes and modifications that can be caused due to a change in manufacturing process. Thus, regions shown in the drawings are illustrated in schematic form and the shapes of the regions are presented simply by way of illustration and not as a limitation.

Hereinafter, a gate all around (GAA) type semiconductor device according to some embodiments of the present inventive concept will now be described with reference to the accompanying drawings.

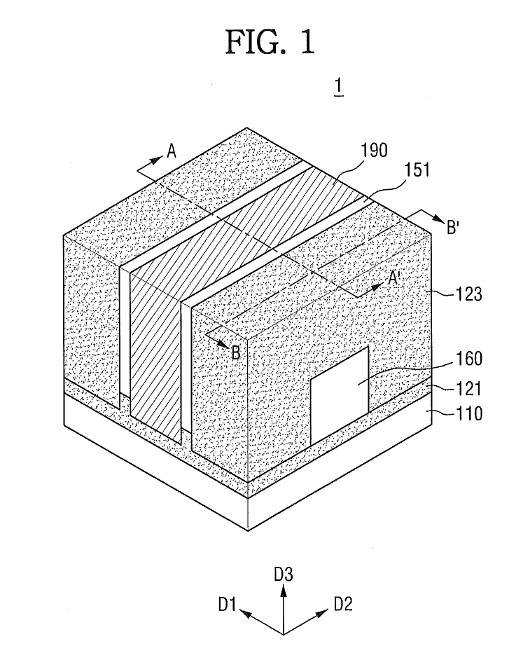

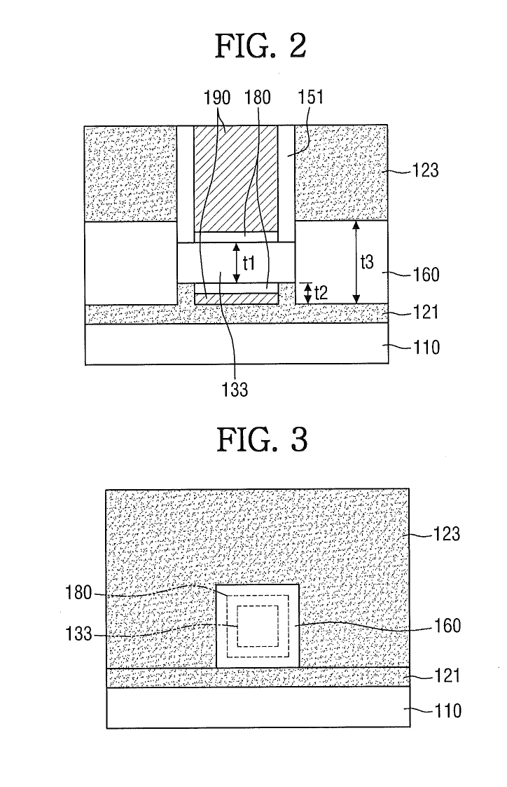

FIG. 1 is a perspective view illustrating a GAA type semiconductor device according to some embodiments of the present inventive concept, FIG. 2 is a cross-sectional view illustrating the GAA type semiconductor device according to some embodiments of the present inventive concept, taken along the line A-A′ of FIG. 1, and FIG. 3 is a cross-sectional view illustrating the GAA type semiconductor device according to some embodiments of the present inventive concept, taken along the line B-B′ of FIG. 1.

Referring to FIGS. 1 to 3, the GAA type semiconductor device 1 according to some embodiments of the present inventive concept includes a channel layer 133, source/drain layers 160, a gate insulation layer 180 and a gate electrode 190, which are formed on a substrate.

In an example embodiment, the substrate may be a silicon on insulator (SOI) substrate. For example, briefly referring to FIG. 9, the SOI substrate may include a first silicon layer 110, a second silicon layer 130, and an insulation layer 120 formed between the pair of silicon layers 110 and 130. In some embodiments, the insulation layer 120 may include silicon oxide or silicon oxynitride, but aspects of the present inventive concept are not limited thereto.

The channel layer 133 having a first thickness t1 may be formed on the substrate. The channel layer 133 may extend in a first direction D1. The channel layer 133 may be formed by patterning the second silicon layer 130. The channel layer 133 may be formed of a nanowire channel. The channel layer 133 shaped of a square pillar is exemplified in FIGS. 1 to 3, but aspects of the present inventive concept are not limited thereto. Rather, the channel layer 133 may have various shapes, including a cylinder, an elliptical cylinder, or the like.

The source/drain layers 160 are spaced apart from each other and may be connected by the channel layer 133. In some embodiments, impurities of at least one material selected from boron (B) and indium (In) or one of boron (B) and indium (In) may be doped into the source/drain layers 160. Each of the source/drain layers 160 may include an upper region formed upper than the channel layer 133 and a lower region formed lower than the channel layer 133. To this end, a portion of the insulation layer 120 may be recessed by a second thickness t2. The source/drain layers 160 may be formed to have a third thickness t3. The source/drain layers 160 may include silicon germanium (SiGe) or silicon carbide (SiC), but aspects of the present inventive concept are not limited thereto. In some embodiments, semiconductor device 1 may have an elevated source drain (ESD) structure, but aspects of the present inventive concept are not limited thereto.

The gate insulation layer 180 is formed along the periphery of at least a portion of the channel layer 133. The gate insulation layer 180 may have a stacked structure of an interface layer and a high-k layer. In some embodiments, the interface layer may include a low-k dielectric material having a dielectric constant (k) of 9 or less, silicon oxide (having k of approximately 4), or silicon oxynitride (having k in a range of approximately 4 to 8 according to the amounts of oxygen and nitrogen atoms), but aspects of the present inventive concept are not limited thereto. The high-k layer may include a high-k dielectric material having a higher dielectric constant (k) than the interface layer. In some embodiments, the high-k layer may include a material selected from the group consisting of HfSiON, HfO₂, ZrO₂, Ta₂O₅, TiO₂, SrTiO₅ and (Ba, Sr)TiO₅, but aspects of the present inventive concept are not limited thereto.

The gate electrode 190 is formed along the periphery of the gate insulation layer 180 in a gate all around (GAA) type. The gate electrode 190 may extend in a second direction D2. The first direction D1 and the second direction D2 may be perpendicular to each other, but aspects of the present inventive concept are not limited thereto. A distance between a bottom surface of the channel layer 133 and a bottom surface of the gate electrode 190 may be equal to the second thickness t2, but aspects of the present inventive concept are not limited thereto. A lower portion of the gate electrode 190 may be formed to the same depth as the lower portions of the source/drain layers 160. In some embodiments, the gate electrode 190 may include a metal layer, a metal silicide layer, or a combination thereof, but aspects of the present inventive concept are not limited thereto.

An insulation pattern 121 may be formed under the gate electrode 190 and under the source/drain layers 160. The insulation pattern 121 may also be formed between the lower portions of the gate electrode 190 and the lower portions of the source/drain layers 160. The insulation pattern 121 may cover portions of sidewalls of the lower portion of the gate electrode 190 and sidewalls of the lower portions of the source/drain layers 160. The insulation pattern 121 may be formed by patterning the insulation layer 120.

A spacer 151 may be formed between upper portions of the gate electrode 190 and upper portions of the source/drain layers 160. The spacer 151 may cover other portions of the sidewalls of the gate electrode 190. In some embodiments, the spacer 151 may include silicon oxide or silicon oxynitride, but aspects of the present inventive concept are not limited thereto.

An interlayer insulation layer 123 covering the source/drain layers 160 and the sidewalls of the spacer 151 may be formed. In some embodiments, the interlayer insulation layer 123 may include a material substantially the same as or different from that of the insulation pattern 121.

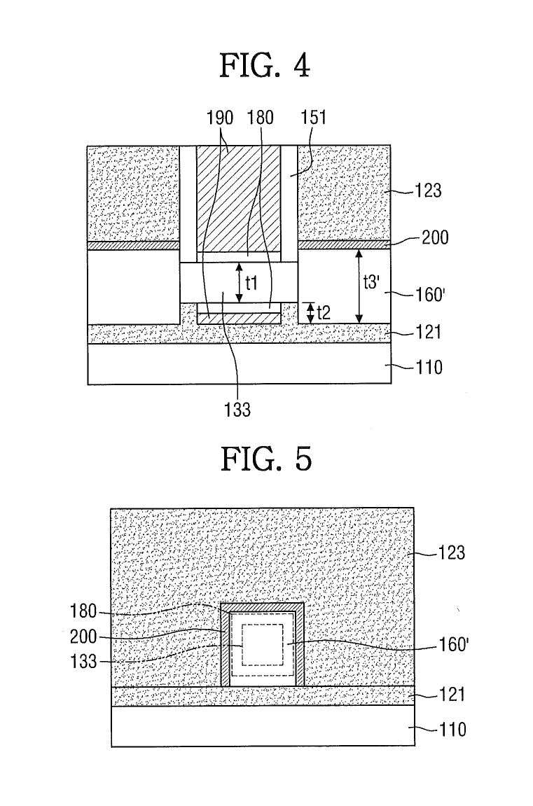

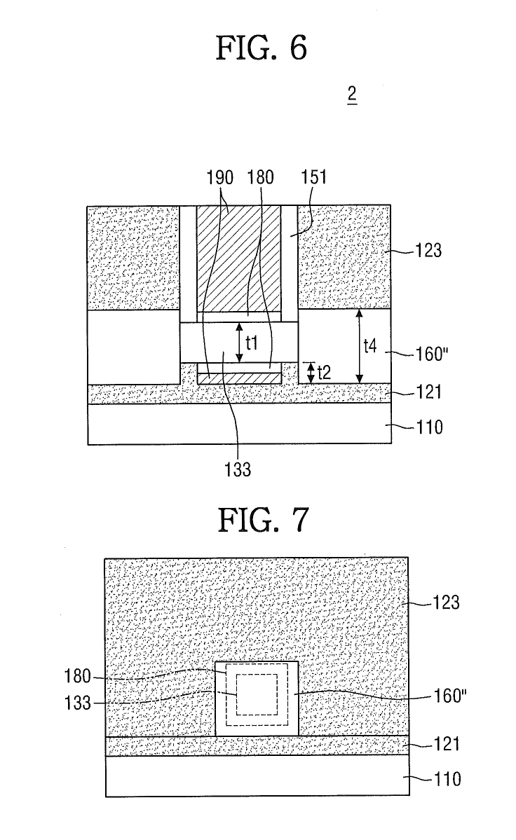

FIG. 4 is a cross-sectional view illustrating an application example of the GAA type semiconductor device according to some embodiments of the present inventive concept, taken along the same line as the line A-A′ of FIG. 1 and FIG. 5 is a cross-sectional view illustrating an application example of the GAA type semiconductor device according to some embodiments of the present inventive concept, taken along the same line as the line B-B′ of FIG. 1. For the sake of convenient explanation, the following description will focus on differences between the GAA type semiconductor device shown in FIG. 4 and the GAA type semiconductor device according to previously disclosed embodiments of the present inventive concept.

Referring to FIGS. 4 and 5, in an application example of the GAA type semiconductor device according to some embodiments of the present inventive concept, a silicide layer 200 may be formed on source/drain layers 160′, and the source/drain layers 160′ may have a reduced thickness, that is, a fourth thickness t3′. In some embodiments, the fourth thickness t3′ may be smaller than the third thickness t3. The silicide layer 200 may be formed to cover top surfaces and sidewalls of the source/drain layers 160. An overall thickness of the silicide layer 200 and the source/drain layers 160′ may be equal to the third thickness t3, but aspects of the present inventive concept are not limited thereto.

FIG. 6 is a cross-sectional view illustrating a GAA type semiconductor device according to some embodiments of the present inventive concept, taken along the same line as the line A-A′ of FIG. 1 and FIG. 7 is a cross-sectional view illustrating the GAA type semiconductor device according to some embodiments of the present inventive concept, taken along the same line as the line B-B′ of FIG. 1. For the sake of convenient explanation, the following description will focus on differences between the GAA type semiconductor devices according to the current and previous embodiments of the present inventive concept.

Referring to FIGS. 6 and 7, source/drain layers 160″ may be formed to have a reduced thickness, that is, a fifth thickness t4. In an example embodiment, the fifth thickness t4 may be smaller than the third thickness t3. Depths of top surfaces of the source/drain layers 160″ may be the same as or smaller than a depth of the top surface of the channel layer 133, but aspects of the present inventive concept are not limited thereto.

The GAA type semiconductor device has several advantages in view of leakage current or performance, but may have a disadvantage in that it has large resistance of a source/drain region. In the GAA type semiconductor devices according to embodiments of the present inventive concept, lower portions of source/drain layers are deeper than a lower portion of a channel layer. Therefore, since a junction depth of the source/drain layers is greater than that of the channel layer, spreading resistance can be generally reduced. Unlike in the conventional GAA type semiconductor device, in which an insulation layer is positioned on lateral surfaces of a lower portion of the channel layer and boosting may not be facilitated, in the GAA type semiconductor devices according to embodiments of the present inventive concept, boosting may be maximized by the source/drain layers. In addition, in the GAA type semiconductor device according to embodiments of the present inventive concept, an area of a silicide layer may be increased, thereby suppressing congestion of current induced into the silicide layer while reducing contact resistance.

Hereinafter, a fabricating method of the GAA type semiconductor device according to some embodiments of the present inventive concept will be described.

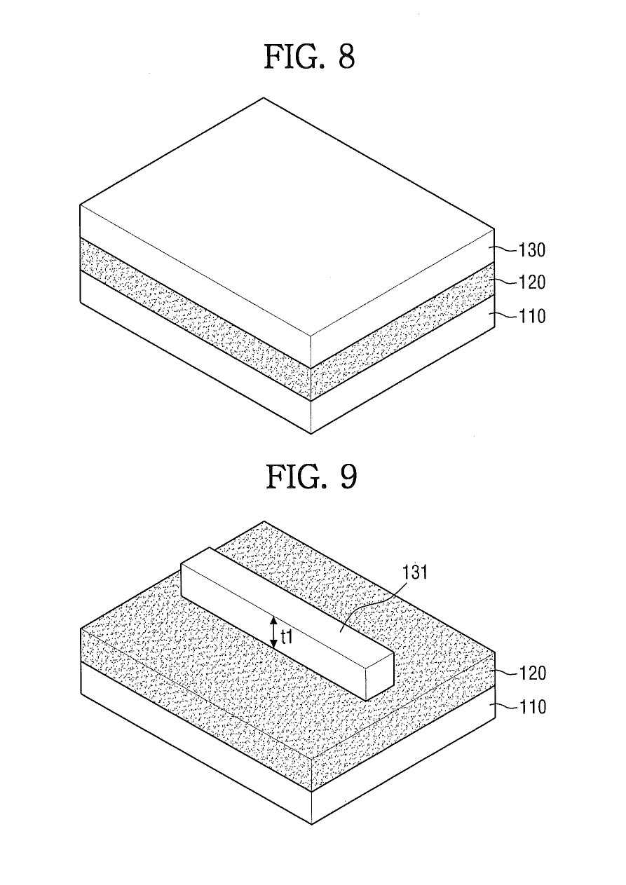

FIGS. 8 to 17 are perspective views illustrating intermediate process operations for explaining a fabricating method of the GAA type semiconductor device according to the first embodiment of the present inventive concept.

Referring to FIG. 8, an SOI substrate is first provided. In an example embodiment, the SOI substrate may include a first silicon layer 110, a second silicon layer 130 and an insulation layer 120 formed between the pair of silicon layers 110 and 130. In some embodiments, the insulation layer 120 may include silicon oxide or silicon oxynitride, but aspects of the present inventive concept are not limited thereto.

Next, referring to FIG. 9, an active region 131 is formed on the SOI substrate. The active region 131 may be formed to a first thickness t1 by patterning the second silicon layer 130. The active region 131 may extend in a first direction D1. In some embodiments, the first thickness t1 may be approximately 10 nm or less, but aspects of the present inventive concept are not limited thereto. However, the present inventive concept does not limit the kind of substrate to the SOI substrate, and a substrate made of a semiconductor material, such as silicon (Si), may be used.

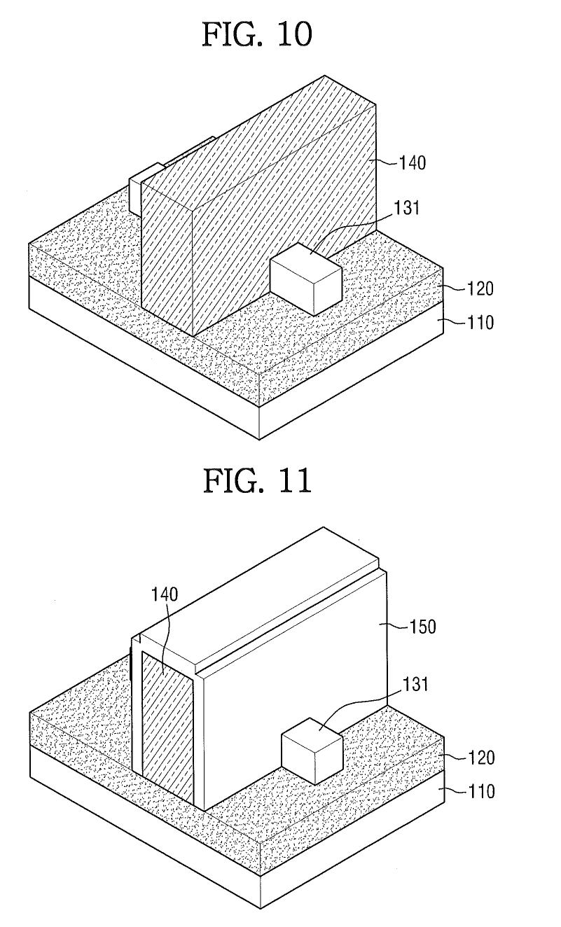

Referring to FIG. 10, a sacrificial gate pattern 140 is formed to cover a top surface of a first region of the active region 131 and sidewalls of the active region 131. The first region of the active region 131 may correspond to the channel layer 133. The sacrificial gate pattern 140 may extend in a second direction D2. The first direction D1 and the second direction D2 may be perpendicular to each other, but aspects of the present inventive concept are not limited thereto. In some embodiments, the sacrificial gate pattern 140 may be made of polysilicon, but aspects of the present inventive concept are not limited thereto.

Next, referring to FIG. 11, a spacer structure 150 covering sidewalls of the sacrificial gate pattern 140 is formed. In more detail, the spacer structure 150 may be formed to cover the top surface and sidewalls of the sacrificial gate pattern 140. In some embodiments, the spacer structure 150 may include silicon oxide or silicon oxynitride, but aspects of the present inventive concept are not limited thereto.

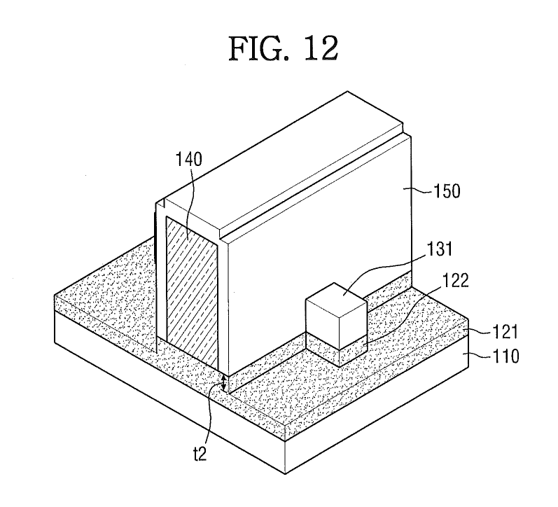

Next, referring to FIG. 12, a portion of the insulation layer (120 of FIG. 11) is removed. In more detail, the insulation layer 120 may be removed as much as a second thickness t2 using a second region of the active region 131 as a mask. The second region of the active region 131 may correspond to an exposed region of the active region 131 without being covered by the sacrificial gate pattern 140 and the spacer structure 150. In some embodiments, the second thickness t2 may be approximately 5 nm or less, but aspects of the present inventive concept are not limited thereto. Accordingly, the insulation layer 120 may include a region 121 resulting after removing the insulation layer 120 by the second thickness t2 and a region 122 positioned under the second region of the active region 131. In some embodiments, the insulation layer 120 may be removed as much as the second thickness t2 by dry etching using etching gas, but aspects of the present inventive concept are not limited thereto.

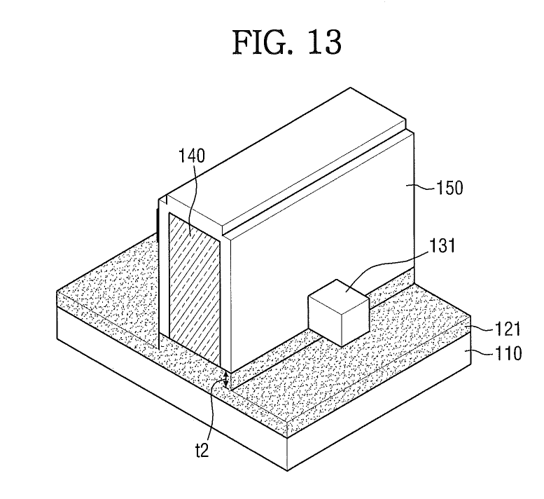

Next, referring to FIG. 13, another portion of the insulation layer 120 is additionally removed. In more detail, the underlying insulation layer 122 of the second region of the active region 131 may be removed. Accordingly, the second region of the active region 131 may be and the insulation pattern 121 may be spaced apart from each other. In some embodiments, in order to remove the insulation layer 122 of the second region of the active region 131, wet etching using an etching solution may be employed, but aspects of the present inventive concept are not limited thereto. To this end, the insulation layer 120 may have a high etching selectivity with respect to the spacer structure 150 and the active region 131.

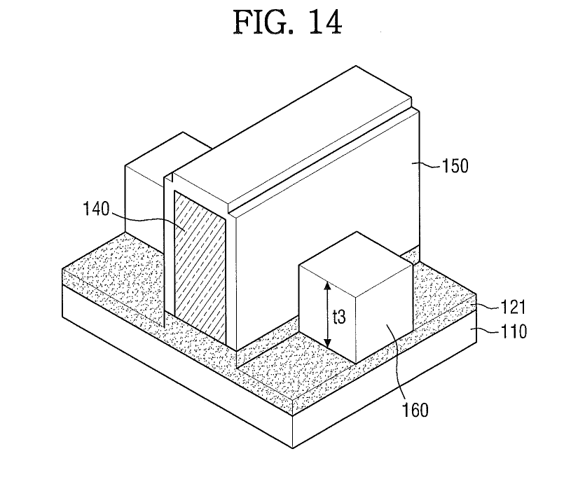

Referring to FIG. 14, germanium (Ge) or carbide (C) is diffused into the second region of the active region 131, followed by performing epitaxial growth, thereby forming the source/drain layers 160. At the same time, impurities may be doped into the source/drain layers 160. Accordingly, the source/drain layers 160 may be spaced apart from each other and may be connected to each other by the channel layer 133. In some embodiments, when the semiconductor device is a p-type transistor, p-type impurity may be doped, and when the semiconductor device is an n-type transistor, n-type impurity may be doped. The p-type impurity may be one material selected from boron (B) and indium (In), and the n-type impurity may be one material selected from arsenic (As) and phosphorus (P), but aspects of the present inventive concept are not limited thereto. The source/drain layers 160 may be epitaxially grown to have a third thickness t3. In some embodiments, the third thickness t3 may be approximately 20 nm or less, but aspects of the present inventive concept are not limited thereto. In some embodiments, the source/drain layers 160 may include silicon germanium (SiGe) or silicon carbide (SiC), but aspects of the present inventive concept are not limited thereto. When the semiconductor device is a p-type transistor, the source/drain layers 160 may include SiGe, and when the semiconductor device is an n-type transistor, the source/drain layers 160 may include SiC.

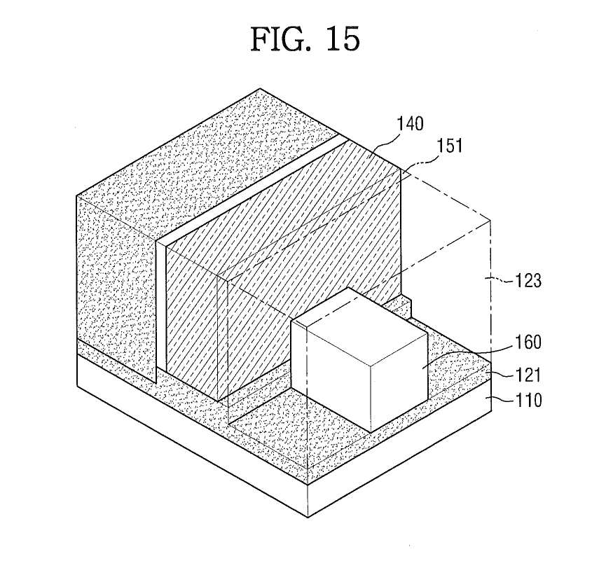

To explain processes for forming the interlayer insulation layer 123, the spacer 151 and the gate insulation layer 180 in detail, the semiconductor device having a see-through side is exemplified in FIGS. 15 to 17. The see-through side of the semiconductor device may have the same configuration as the other side of the semiconductor device.

Next, referring to FIG. 15, an interlayer insulation layer 123 covering the source/drain layers 160 and the spacer structure 150 is formed. In some embodiments, the interlayer insulation layer 123 may be formed of a material the same as or different from that of the insulation pattern 121. Next, the spacer structure 150 and the interlayer insulation layer 123 are removed until a top surface of the sacrificial gate pattern 140 is exposed. In some embodiments, in order to remove portions of the spacer structure 150 and the interlayer insulation layer 123, a chemical mechanical polishing (CMP) process may be used, but aspects of the present inventive concept are not limited thereto. Accordingly, a pair of spacers 151, covering sidewalls of the sacrificial gate pattern 140, are formed.

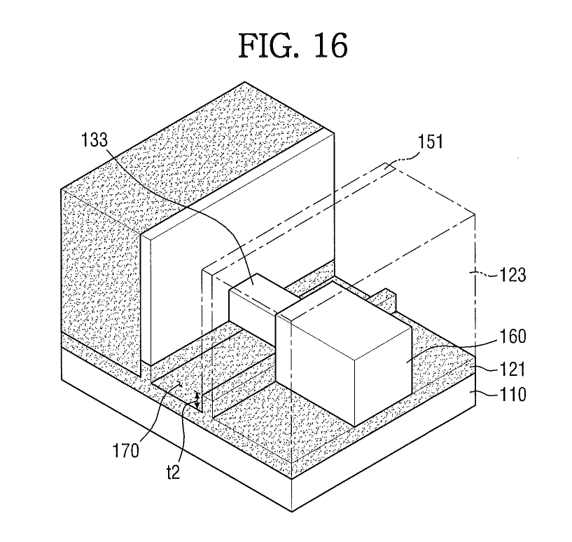

Next, referring to FIG. 16, the sacrificial gate pattern 140 is removed. Accordingly, an opening 170 is formed, the opening 170 exposing the channel layer 133 between the pair of spacer 151. Here, the channel layer 133 may make contact with the insulation pattern 121. Then, the insulation pattern 121 under the channel layer 133 is removed. In more detail, the insulation pattern 121 under the channel layer 133 may be removed as much as the second thickness t2, but aspects of the present inventive concept are not limited thereto. The opening 170 may extend in a third direction D3. Accordingly, at least a portion of the channel layer 133 and the insulation pattern 121 may be spaced apart from each other, and the periphery of at least the portion of the channel layer 133 may be exposed. In some embodiments, in order to remove the insulation pattern 121 under the channel layer 133, dry etching using an etch gas or wet etching using an etching solution may be employed, but aspects of the present inventive concept are not limited thereto.

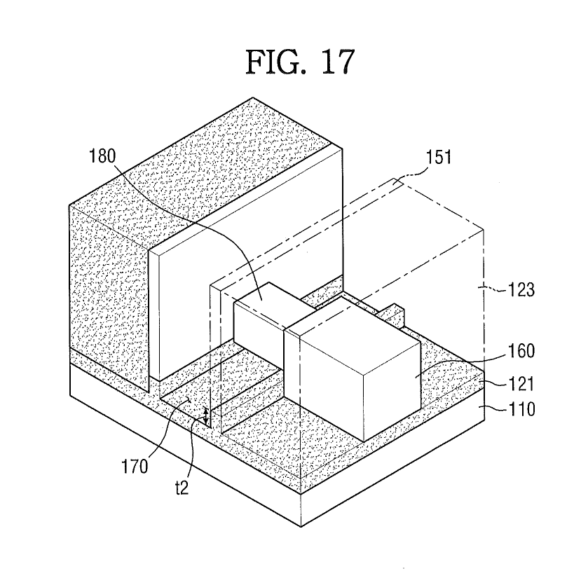

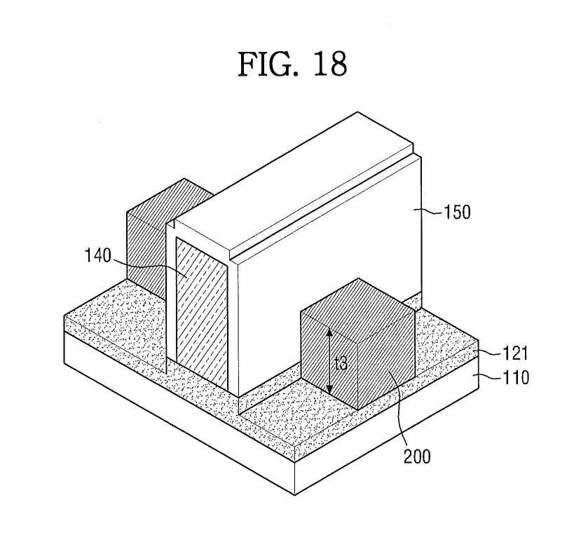

Next, referring to FIG. 17, a gate insulation layer 180 may be formed along the periphery of at least the portion of the channel layer 133. In some embodiments, in order to form the gate insulation layer 180, an atomic layer deposition (ALD) process may be employed, but aspects of the present inventive concept are not limited thereto. The gate insulation layer 180 may be formed to have a stacked structure of an interface layer and a high-k layer. In some embodiments, the interface layer may include a low-k dielectric material having a dielectric constant (k) of 9 or less, silicon oxide (having k of approximately 4), or silicon oxynitride (having k in a range of approximately 4 to 8 according to the amounts of oxygen and nitrogen atoms), but aspects of the present inventive concept are not limited thereto. The high-k layer may include a high-k dielectric material having a higher dielectric constant (k) than the interface layer. In some embodiments, the high-k layer may include a material selected from the group consisting of HfSiON, HfO₂, ZrO₂, Ta₂O₅, TiO₂, SrTiO₅ and (Ba, Sr)TiO₅, but aspects of the present inventive concept are not limited thereto.

Next, referring again to FIG. 1, a gate electrode 190 may be formed along the periphery of the gate insulation layer 180. In more detail, the opening 170 is filled with a gate electrode material, thereby forming the gate electrode 190. In some embodiments, the gate electrode 190 may include a metal layer, a metal silicide layer, or a combination thereof, but aspects of the present inventive concept are not limited thereto.

Hereinafter, a fabricating method of an application example of the GAA type semiconductor device according to some embodiments of the present inventive concept will be described.

FIG. 18 is a perspective view illustrating an intermediate process operation for explaining a fabricating method of an application example of the GAA type semiconductor device according to some embodiments of the present inventive concept. For the sake of convenient explanation, the following description will focus on differences between the fabricating methods according to the current and previous embodiments of the present inventive concept.

Referring to FIG. 18, after epitaxially growing the source/drain layers 160, a silicide layer 200 is formed on the source/drain layers 160. The silicide layer 200 may be formed by silicidation. Exposed surfaces of the source/drain layers 160 are silicidated, thereby forming the silicide layer 200 so as to cover the top surfaces and sidewalls of the source/drain layers 160′. Accordingly, the source/drain layers 160′ may have a reduced thickness, that is, a fourth thickness t3′. In some embodiments, the fourth thickness t3′ may be smaller than the third thickness t3. Since the subsequent process operations may be substantially the same as those described above, further detailed descriptions will be omitted.

Hereinafter, a fabricating method of an application example of the GAA type semiconductor device according to some other embodiments of the present inventive concept will be described.

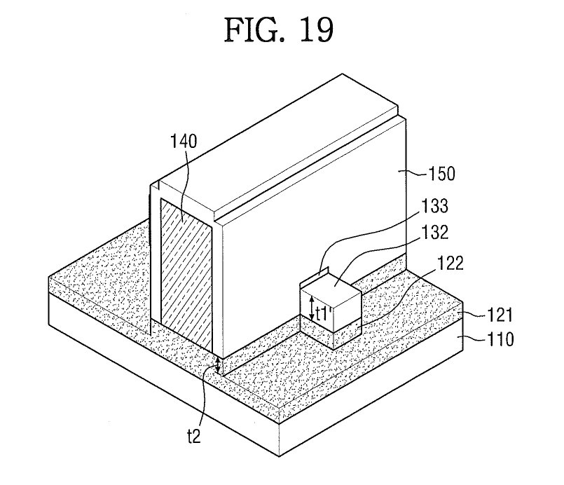

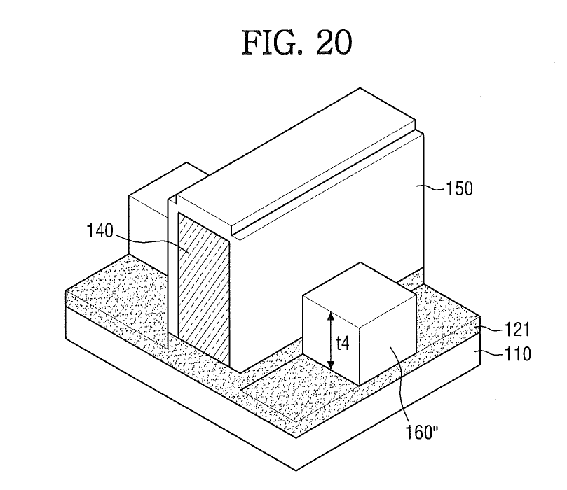

FIGS. 19 and 20 are perspective views illustrating intermediate process operations for explaining a fabricating method of the GAA type semiconductor device according to the second embodiment of the present inventive concept. For the sake of convenient explanation, the following description will focus on differences between the fabricating methods according to the current and previous embodiments of the present inventive concept.

Referring to FIG. 19, when the insulation layer 120 is removed by the second thickness t2, a portion of the second region of the active region 131 may also be removed. Reference numeral 132 refers to a second region from which a portion of the active region 131 is removed. A thickness t1′ of the second region 132 of the active region 131 may be smaller than the first thickness t1. Since a first region of the active region 131 is protected by the spacer structure 150, a thickness of the channel layer 133 may be maintained at the first thickness t1.

Referring to FIG. 20, the second region 132 of the active region 131 is epitaxially grown, thereby forming source/drain layers 160″. When the insulation layer 120 is removed by the second thickness t2, a portion of the second region 132 of the active region 131 is also removed, the source/drain layers 160″ may be grown to have a reduced thickness, that is, a fifth thickness t4. In some embodiments, the fourth thickness t4 may be smaller than the third thickness t3.

Since the subsequent process operations may be substantially the same as those of the fabricating method of the GAA type semiconductor device according to embodiments described herein, further detailed descriptions will be omitted.

The semiconductor devices according to some embodiments of the present inventive concept may be mounted as various types of packages.

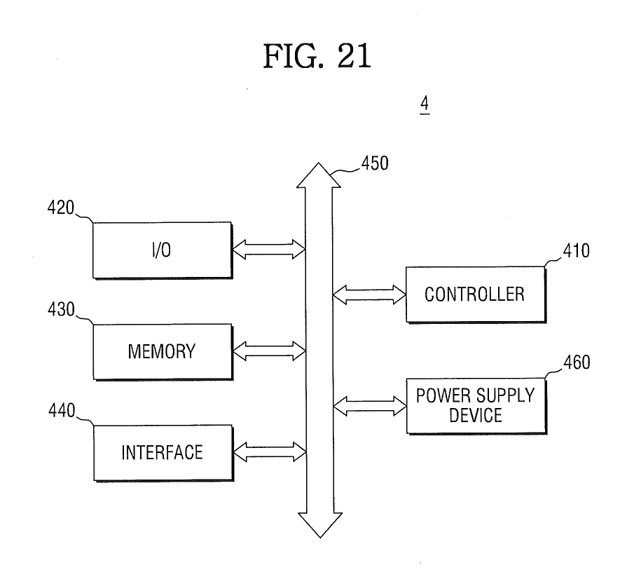

FIG. 21 is a block diagram of an electronic system including semiconductor devices according to some embodiments of the present inventive concept.

Referring to FIG. 21, the electronic system 4 may include a controller 410, an input/output device (I/O) 420, a memory 430, an interface 440, a power supply device 460 and a bus 450.

The controller 410, the input/output device (I/O) 420, the memory 430, and/or the interface 440 may be connected to each other through the bus 450. The bus 450 corresponds to a path along which data moves.

The controller 410 may include at least one of a microprocessor, a digital signal processor, a microcontroller, and logic devices capable of performing functions similar to those of these components.

The I/O 420 may include a keypad, a keyboard, a display, and so on.

The memory 430 may store data and/or commands.

The interface 440 may transmit data to a communication network or receive data from the communication network. The interface 440 may be wired or wireless. For example, the interface 440 may include an antenna or a wired/wireless transceiver.

The power supply device 460 converts externally applied power and supplies the same to various components 410, 420, 430 and 440. One or more power supply devices 460 may be provided in the electronic system 4.

Although not shown, the electronic system 4 is an operating memory for improving the operation of the controller 410 and may further include a high-speed DRAM and/or SRAM.

The semiconductor devices 1 and 2 according to some embodiments of the present inventive concept may be provided into the memory 430 or may be provided as part of the controller 410 or the I/O 420.

The electronic system 4 may be provided as one of various components of an electronic device such as a computer, a mobile device, a multimedia device, or the like.

It is within the spirit and scope disclosed herein that at least one of the semiconductor devices according to some embodiments of the present inventive concept can be applied to other integrated circuit devices not illustrated herein.

In concluding the detailed description, those skilled in the art will appreciate that many variations and modifications can be made to the preferred embodiments without substantially departing from the principles of the present inventive concept. Therefore, the disclosed embodiments of the invention are used in a generic and descriptive sense only and not for purposes of limitation.

What is claimed is:

1. A semiconductor device, comprising:
source/drain layers that are formed at a first depth in a substrate and spaced apart from each other;
a channel layer that are formed at a second depth in the substrate that is less deep than the first depth and connecting the source/drain layers;
a gate electrode that is formed along a periphery of at least a portion of the channel layer; and
an insulation pattern that is formed between lower portions of the source/drain layers and corresponding lower portions of the gate electrode.

2. The semiconductor device according to claim 1, wherein each of the source/drain layers comprises an upper region that is formed higher than the channel layer.

3. The semiconductor device according to claim 2, wherein each of the source/drain layers comprise a lower region that is formed lower than the channel layer.

4. The semiconductor device according to claim 1, wherein a lower portion of the gate electrode is formed to about the first depth.

5. The semiconductor device according to claim 1, further comprising a gate insulation layer that surrounds the periphery of at least a portion of the channel layer and that is positioned between the channel layer and the gate electrode.

6. The semiconductor device according to claim 1, further comprising a spacer that is formed between upper portions of the gate electrode and upper portions of the source/drain layers.

7. The semiconductor device according to claim 1, wherein the insulation pattern extends to the lower portions of the gate electrode and to the lower portions of the source/drain layers.

8. The semiconductor device according to claim 1, wherein the source/drain layers include silicon germanium (SiGe) or silicon carbide (SiC).

9. The semiconductor device according to claim 1, further comprising a silicide layer formed on the source/drain layers.

10. The semiconductor device according to claim 1, further comprising an interlayer insulation layer covering the source/drain layers and sidewalls of the spacer.

11. A semiconductor device comprising:
source/drain layers formed to be spaced apart from each other;
a channel layer connecting the source/drain layers;
a gate electrode formed along a periphery of at least a portion of the channel layer;
a gate insulation layer surrounding the periphery of at least a portion of the channel layer and positioned between the channel layer and the gate electrode; and
a spacer formed between upper portions of the gate electrode and between upper portions of the source/drain layers,
wherein a lower portion of the gate electrode is formed to the same depth as the lower portions of the source/drain layers.

12. The semiconductor device according to claim 11, wherein an insulation pattern is formed between the lower portions of the source/drain layers and lower portions of the gate electrode.

13. The semiconductor device according to claim 12, wherein the insulation pattern extends to the lower portion of the gate electrode and to the lower portions of the source/drain layers.

14. The semiconductor device according to claim 11, wherein each of the source/drain layers includes an upper region formed upper than the channel layer and a lower region formed lower than the channel layer.

15. The semiconductor device according to claim 11, further comprising a silicide layer formed on the source/drain layers.

16. The semiconductor device according to claim 11, wherein the source/drain layers include silicon germanium (SiGe) or silicon carbide (SiC).

17. The semiconductor device according to claim 11, further comprising an interlayer insulation layer covering the source/drain layers and sidewalls of the spacer.

18. A semiconductor device, comprising:
source/drain layers that are formed at a first depth in a substrate and spaced apart from each other;
a silicide layer formed on the source/drain layers;
a channel layer that are formed at a second depth in the substrate that is less deep than the first depth and connecting the source/drain layers;
a gate electrode that is formed along a periphery of at least a portion of the channel layer;
a gate insulation layer that surrounds the periphery of at least a portion of the channel layer and that is positioned between the channel layer and the gate electrode;
a spacer that is formed between upper portions of the gate electrode and upper portions of the source/drain layers;
an interlayer insulation layer covering the source/drain layers and sidewalls of the spacer; and
an insulation pattern that is formed between lower portions of the source/drain layers and corresponding lower portions of the gate electrode.

19. The semiconductor device according to claim 18, wherein each of the source/drain layers comprises an upper region that is formed higher than the channel layer, and
wherein each of the source/drain layers comprise a lower region that is formed lower than the channel layer.

20. The semiconductor device according to claim 18, wherein a lower portion of the gate electrode is formed to about the first depth.
